(19) United States
(12) Patent Application Publication
(10) Pub. No.: US 2012/0211448 A1
(43) Pub. Date: Aug. 23, 2012

(54) PAN AND TILT DRIVE SYSTEM

(76) Inventor: Philip A. Markey, Carine WA (AU)

(21) Appl. No.: 13/402,604

(22) Filed: Feb. 22, 2012

Related U.S. Application Data
(60) Provisional application No. 61/463,574, filed on Feb. 22, 2011.

(51) Int. Cl. H05K 7/18; F16H 35/00; H05K 7/00

(52) U.S. Cl. 211/26; 248/278.1; 74/89

(57) ABSTRACT

A pan and tilt drive system for an electrically powered device includes a housing in which an elongated shaft is rotatably supported, which shaft is rotatably driven about a shaft axis by a pan motor. A receptacle is coupled to the shaft and disposed to pivot about a tilt axis which tilt axis is perpendicular to the shaft axis. A tilt subsystem is provided to facilitate tilt motion of the receptacle about the tilt axis. The tilt subsystem includes a tilt motor, a tilt coupling and a tilt rod. The tilt coupling is coupled between the tilt motor and the tilt rod, while the tilt rod is coupled between the tilt coupling and the receptacle. Actuation of the tilt motor effects linear translation of the tilt coupling in a direction parallel to the shaft axis, thereby causing the tilt rod to tilt the receptacle about the tilt axis.

### CROSS-REFERENCE TO RELATED APPLICATION

The present application claims priority from U.S. Provisional Patent Application 61/463,574, filed Feb. 22, 2011, the entire contents of which is specifically incorporated herein by reference in its entirety.

### FIELD OF THE INVENTION

The present invention relates to a pan and tilt drive system of the type that may provide pan and tilt motion to an electrically coupled device such as but not limited to a light source or camera.

### BACKGROUND OF THE INVENTION

Pan and tilt drive systems are used in many applications including in the security industry to enable positioning or steering of cameras and in the entertainment industry to control lighting. An example of a pan and tilt drive system is described in U.S. Pat. No. 6,027,257. This describes a pan and tilt system having separate pan and tilt motors disposed in a common housing. The system comprises a platform rotatable about a first axis within a housing, and a tilt bed pivotally coupled about a transverse tilt axis to the platform. Separate motors are arranged to rotate the platform about the pan axis and the tilt bed about the tilt axis. As a result of coupling the tilt bed to the platform, tilt angle is limited to approximately ±30°.

### SUMMARY OF THE INVENTION

In one aspect the invention provides a pan and tilt drive system for an electrically powered device, and includes a housing; a shaft rotatably supported in the housing; a pan motor disposed to rotate the shaft about a longitudinal axis of the shaft; a receptacle coupled to the shaft about a tilt axis, the receptacle arranged to support an electrically powered device; and a tilt subsystem disposed to facilitate tilt motion of the receptacle about the tilt axis, the tilt subsystem having a tilt motor disposed in the housing, a tilt coupling and a tilt rod, the tilt coupling coupled between the tilt motor and the tilt rod, and the tilt rod coupled between the tilt coupling and the receptacle, the tilt coupling arranged to effect linear translation of the tilt rod in a direction parallel to the longitudinal axis to effect tilt motion of the receptacle about the tilt axis.

In one embodiment, the tilt coupling is slidably supported on the shaft.

In one embodiment the tilt coupling comprises a sleeve mounted on the shaft and a tilt link carried by the sleeve and rotationally decoupled from the sleeve.

In one embodiment, the sleeve is provided with axially spaced apart stops between which the tilt link is retained.

In one embodiment, each stop comprises a ring extending radially from and circumferentially about the sleeve.

In one embodiment, the tilt link comprises a bearing block coupled to the tilt motor, wherein operation of the tilt motor effects a linear motion of the bearing block along the longitudinal axis, and wherein the tilt rod is coupled to the sleeve.

In an alternate embodiment, the tilt link comprises a slip ring retained on the sleeve and a member having first and second opposite ends, the member pivotally connected intermediate of its ends to the slip ring, wherein the first end of the member is coupled the tilt motor wherein operation of the tilt motor effects a pivoting of the member, and wherein the tilt rod is connected to the second end of the member.

In one embodiment, the receptacle is suspended from the housing.

In one embodiment, the housing comprises a plate through which the shaft and tilt rod extend at offset locations, the plate being rotatably supported in the housing in a plane perpendicular to the longitudinal axis.

In one embodiment, the shaft is extendable and retractable along the longitudinal axis in the receptacle is movable between a retracted position where the receptacle is disposed within the housing and an extended position where the receptacle is disposed outside of the housing.

In one embodiment, the pan and tilt drive system further comprises an electrical conductor extending through the housing, the electrical conductor enabling flow of electric current between an electric power source and an electrically powered device engaged in the receptacle.

In one embodiment, the electrical conductor passes through the shaft.

In one embodiment, the pan and tilt drive system comprises an electrical connector disposed in the receptacle, the electrical connector electrically coupled to the electrical conductor and configured to electrically connect to an electrically powered device.

In one embodiment, the pan and tilt drive system comprises a control system arranged to control one or more of: the pan motor, the tilt motor and an electrically powered device engaged in the receptacle.

In one embodiment, the control system comprises one or more processors disposed in one or both of the housing and the receptacle.

In one embodiment, one or more of the processors comprise an associated electronic memory.

In one embodiment, the pan and tilt drive system comprises a communications system enabling either or both signals and data to be communicated between a remote device and the control system to control one or more of: the pan motor, the tilt motor and an electrically powered device.

In one embodiment, the receptacle is arranged to engage a plurality of electrically powered devices.

In one embodiment, two or more of the plurality of electrically powered devices produce different outputs.

In one embodiment a pan and tilt drive system for an electrically powered device includes a housing; a shaft having a first end and a second end and characterized by a shaft axis, wherein the shaft is rotatably supported in the housing; a first motor disposed to rotate the shaft about the shaft axis; a mounting plate pivotally attached to one end of the shaft, wherein the mounting plate pivots about a tilt axis that is perpendicular to the shaft axis; a sleeve slidingly mounted on the shaft; tilt linkage engaging the plate and the sleeve; and a second motor coupled to the sleeve to urge the sleeve axially along the shaft axis.

In one embodiment, the pan and tilt drive system further includes an elongated, threaded rod coupled to the second motor, the threaded rod extending substantially parallel to the shaft axis, the second motor disposed to cause rotation of the threaded rod; first and second stops mounted on the sleeve and axially spaced apart from one another; a bearing block mounted on the sleeve between the two stops, the bearing block including a threaded through-bore disposed substantially parallel to the shaft axis, wherein the threaded rod threadingly engages the threaded through-bore, wherein the bearing block is axially and rotationally decoupled from the sleeve.

In one embodiment, the shaft of the pan and tilt drive system includes a first portion and a second portion, wherein the second portion of the shaft is mounted in the first portion of the shaft and axially movable relative thereto, wherein the shaft further includes an engagement mechanism to fix relative movement of the first and second portions.

### BRIEF DESCRIPTION OF THE DRAWINGS

Notwithstanding any other forms which may fall within the scope of the pan and tilt drive system as set forth in the Summary, specific embodiments will now be described, by way of example only, with reference to the accompanying drawings in which:

FIG. 1 is a schematic representation of one embodiment of a plan and tilt drive system in accordance with the present invention;

FIG. 2 is a plan view of a portion of a tilt coupling incorporated in the pan and tilt drive system shown in FIG. 1;

FIG. 3 is a schematic representation of a sleeve incorporated in the pan and tilt drive system;

FIG. 4 is a schematic representation of an electrical coupling incorporated in the pan and tilt drive system;

FIG. 5 is a schematic representation of a second embodiment of the pan and tilt drive system;

FIG. 6 is an enlarged view of a portion of the second embodiment of the pan and tilt drive system;

FIG. 7 is a schematic representation of a form of receptacle which may be incorporated in an alternate embodiment of the pan and tilt drive system; and,

FIG. 8 is a schematic representation of a further embodiment of the pan and tilt drive system incorporating an alternate form of tilt coupling.

### DETAILED DESCRIPTION OF THE PREFERRED EMBODIMENT

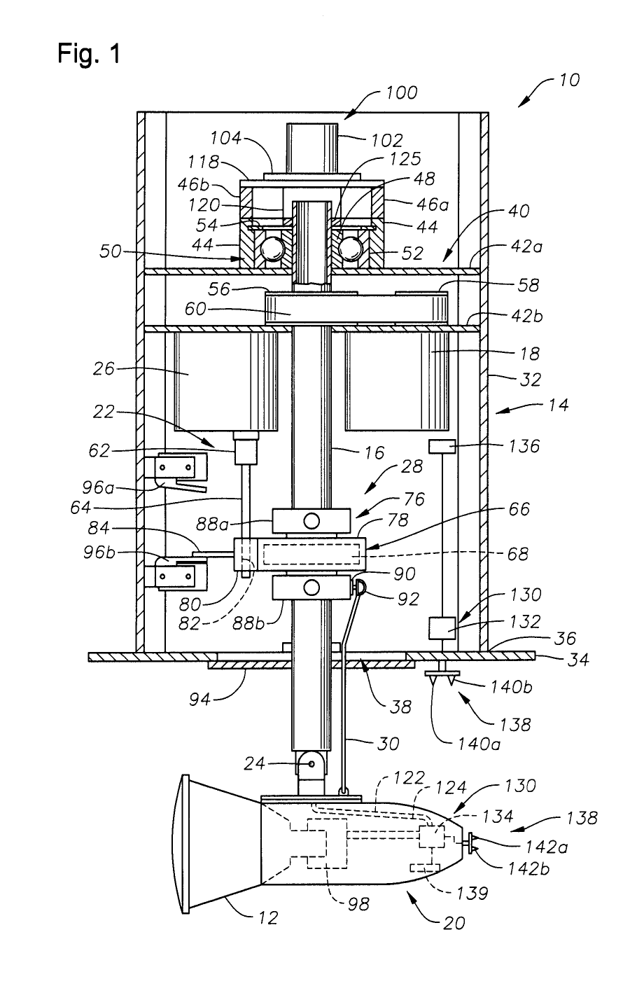

FIG. 1 provides a schematic representation of an embodiment of a pan and tilt drive system 10 (herein after referred to in general as “system 10”) to provide pan and tilt motion to an electrically powered device 12. As will be explained in greater detail below, the electrically powered device 12 is of itself immaterial to the present invention and may comprise one of a plurality of different devices such as, but not limited to, a light source, projector, speaker and camera. Indeed in further embodiments a plurality of different electronically powered devices may be operatively associated with the system 10.

The system 10 comprises a number of components, parts and subsystems which interact to provide pan and tilt motion to an electrically powered device 12. These components parts in subsystems include a housing 14, a shaft 16, a pan motor 18, a receptacle 20 and a tilt subsystem 22. The housing 14 is in the general form of a canister or cylindrical housing and in many embodiments the housing 14 is formed with the same outer dimensions as a conventional down light canister. In such embodiments, the system 10 can be mounted in exactly the same way as a recessed light (also known as a down light). In one embodiment, receptacle 20 is a mounting plate to which an electrical component, such as a light assembly, a speaker assembly, a camera or similar device, may be attached. In another embodiment, receptacle 20 may be a housing in which a light assembly, a speaker assembly, a camera or similar device, may be disposed.

The shaft 16 is rotatably supported in the housing 14. Pan motor 18 is likewise supported in the housing 14 and is arranged to rotate the shaft 16 about a longitudinal axis of the shaft 16. The receptacle 20 is coupled to the shaft 16 about a tilt axis 24. The tilt subsystem 22 is coupled between the housing 14 and the receptacle 20 to facilitate tilt motion of the receptacle 20 about the tilt axis 24. The tilt subsystem 22 has a tilt motor 26 disposed within the housing, a tilt coupling 28 which is also disposed in the housing 14, and a tilt rod, arm, bar, flexible cord or similar tilt linage 30. The tilt coupling 28 couples the tilt motor 26 to the tilt rod 30. The tilt rod 30 is coupled between the tilt coupling 28 and the receptacle 20. As will be described in greater detail below, the tilt coupling 28 is arranged to effect linear translation of the tilt rod 30 in a direction parallel to the shaft 16 to provide tilt motion of receptacle 20 about the tilt axis 24. Thus operating the pan motor 18 enables the receptacle 20 to be rotated about the longitudinal axis of the shaft 16 while operation of the pan motor 26 enables the receptacle 20 to be pivoted up about the axis 24. In this embodiment the axis 24 extends perpendicular to the shaft 16.

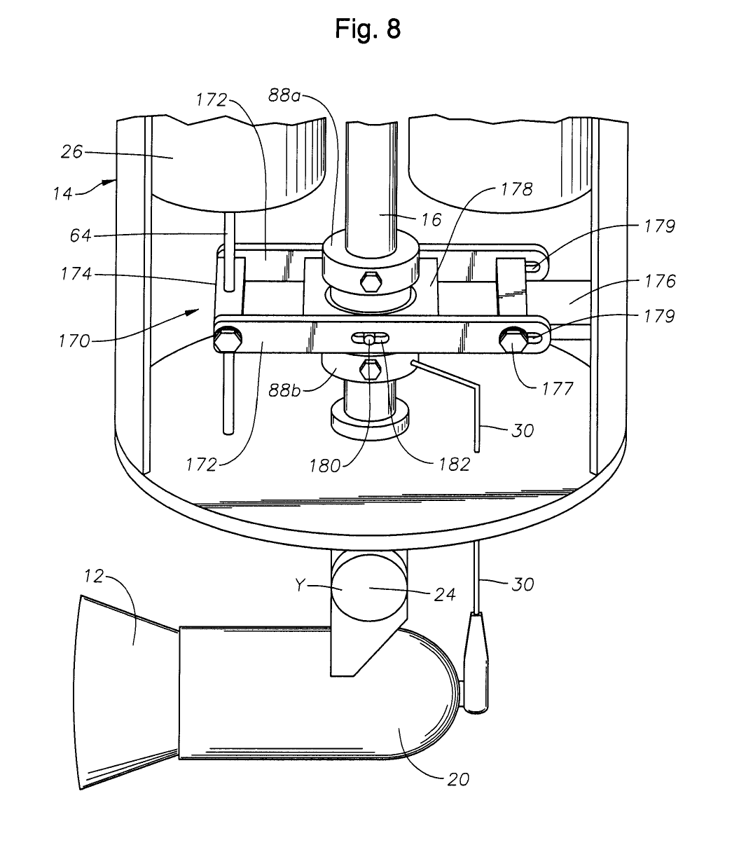

It will be noted that in the depicted embodiment the receptacle 20 is suspended by the shaft 16 from the housing 12 and indeed is disposed beneath the housing 14. As a consequence, in embodiments of the system 10, it is possible for the receptacle 20 to be tilted by up to ±90° from a horizontal plane containing the tilt axis 24. The actual tilt angle or tilt range will only be limited by the physical arrangement of the receptacle 20 and shaft 16 so that they do not hit each other during a tilt motion. Moreover, by providing alternate mechanical couplings for example a yolk coupling Y (shown in FIG. 8), it is possible to achieve a full ±90° tilt angle. It should be understood that tilting of the receptacle 20 in a clockwise direction by 90° will result in the output of the electrically powered device 12 being directed into the housing 14. However of course if multiple devices 12 are fitted to the receptacle 20, it may be possible to have one of the devices arranged so that when one device is pointing directly into the housing 14 the other is pointing directly downwardly of the housing 14. In embodiments of the system 10 it is possible to activate or power the devices 12 separately so that in the above described configuration the device pointing directly into the housing 14 can be deactivated.

Looking at the system 10 in more detail, the housing 14 has a cylindrical side wall 32. A flange 34 is attached at one end 36 of the cylindrical wall 32. The flange has a configuration of a planar annulus with an outer diameter extending beyond the diameter of the cylindrical wall 32, and an inner diameter less than the inner diameter of the wall 32. The inner diameter of the flange 34 defines an opening 38 through which the shaft 16 and rod 30 extend to connect to the receptacle 20. A support bracket 40 is fitted within the housing 14. The support bracket 40 supports the pan and tilt motors 18, as well as the shaft 16. The support bracket 40 comprises a pair of parallel spaced apart plates 42a and 42b which are fixed to the inside of wall 32. Each plate 42a and 42b is provided with a central hole through which the shaft 16 extends. Plate 42a also seats a circular bearing housing 44 from which extends a pair of diagonally opposed arms 46a and 46b.

The shaft 16 is held with an interference fit in an inner race 48 of a ball bearing 50. An outer race 52 of the ball bearing is fixed within the bearing housing 44 and retained by a circlip 54. The shaft 16 passes through and is rotationally fixed with a cog 56 located between the plates 42a and 42b. The motor 18 is provided with a shaft cog 58 which is also located between the plates 42a and 42b and in lateral alignment with the cog 56. A pulley belt 60 extends about the cogs 56 and 58. Thus torque generated by the motor 18 is transferred via the shaft cog 58, pulley belt 60 and the cog 56 to the shaft 16.

The tilt motor 26 is provided with an output shaft 62 which in turn is coupled to an elongated threaded rod 64. The threaded rod 64 engages the tilt coupling 28 to in effect form a linear actuator.

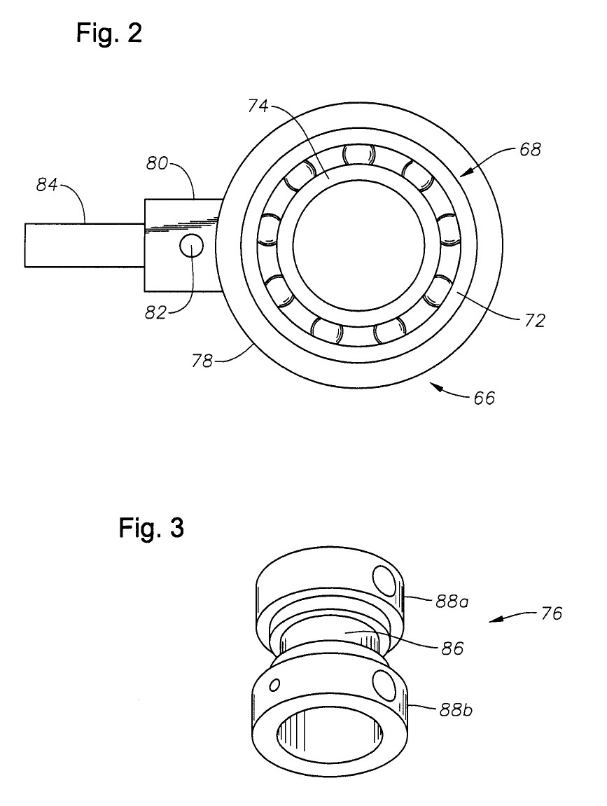

With particular reference to FIGS. 1 and 2, the tilt coupling 28 comprises a bearing block 66 which seats a ball bearing 68. An outer race 72 of the ball bearing 68 is rotationally fixed to the bearing block 66. An inner race 74 of ball bearing 68 is rotationally fixed to a sleeve 76 of the tilt coupling 28. The bearing block 66 comprises a ring portion 78 which surrounds the ball bearing 68, and an integral nut portion 80. The nut portion 80 is formed with a threaded through bore or hole 82 which is engaged by the threaded rod 64. An arm 84 extends from the nut portion 80 in a generally radial outward direction relative to the ring portion 78.

With particular reference to FIG. 3, it will be seen that the sleeve 76 comprises a tube 86 having an inner diameter greater than the outer diameter of the shaft 16, and first and second stops 88a and 88b attached at axially opposite ends of the tube 86. In the construction of the system 10, the tube 86 is first passed through the inner race 74. An interference fit may be formed between the tube 86 and the race 74. However this is not entirely necessary. Next, the stops 88a and 88b are passed onto opposite ends of the tube 86 and fastened thereto for example by way of grub screws (not shown). The assembly of the bearing block 66 on the sleeve 76 can then be slid onto the shaft 16. Subsequently threaded rod 64 can be threadingly engaged with the threaded hole 82. It will be appreciated that now the shaft 16 can rotate within the sleeve 76. Further, the sleeve 76 can rotate within and relative to the bearing block 66 which is held rotationally stationary by reason of engagement with the threaded rod 64. By operating the tilt motor 26 to rotate in opposite directions the threaded rod 64 either screws into or out of the threaded hole 82 causing the sleeve 76 to slide linearly along the shaft 16.

As the tilt rod 30 is attached to the sleeve 76, the linear motion of the sleeve 76 results in the tilt rod 30 either pulling or pushing the receptacle 20 to pivot about the tilt axis 24 in an anticlockwise or clockwise direction respectively. The tilt rod 30 has an articulated joint connection with the sleeve 76. The articulated joint is effected by way of a ball joint pin 56 which is attached to the stop 88b and a ball joint fixing 92 which engages the ball joint pin 90.

The opening 38 in the flange 34 is closed by a disc 94 which rotates within the opening 38. The disc 94 is fixed to the shaft 16 and thus rotates with the shaft 16. Both the shaft 16 and the tilt rod 30 pass through the disc 94.

FIG. 1 depicts optional limit switches 96a and 96b fixed to the inside of the housing 14 at spaced apart locations. The limit switches 96a and 96 are disposed so that they can be tripped by the arm 84. The switches 96 are positioned to limit the linear motion of the tilt coupling 28 and thus limit the degree of tilt of the receptacle 20. To this end the switches 96 can be connected to a controller of the motor 26 which is subsequently arranged to de-energise the motor 26 when one of the switches 96 is tripped.

An electrical connector such as a socket 98 is disposed in the receptacle 20 to enable engagement and/or electrical coupling of the electrically powered device 12. Electric current for operating the electrically powered device 12 is provided by electrical conductors which are electrically connected at one end to a power source (not shown), extend through the shaft 16 and connect at their opposite end to the socket 98. In this embodiment, a rotatable electrical coupling 100 is provided at an end of the shaft 16 distant the receptacle 20. The rotatable electrical coupling 100 is in the form of slip rings and contact brushes.

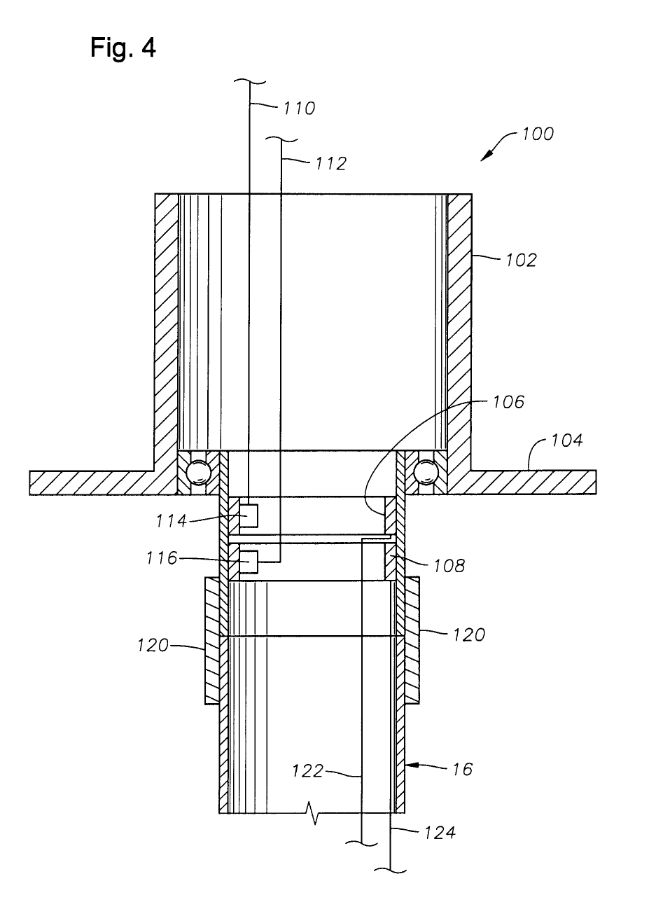

With particular reference to FIG. 4 the rotatable electrical coupling 100 comprises a slip ring body 102 having a peripheral flange 104. Two slip rings 106 and 108 are rotatably supported in the body 102. The slip rings 106 and 108 are mechanically connected together but electrically isolated from each other. Both of the slip rings 106 and 108 are able to rotate relative to the body 102. Power cables 110 and 112 are connected at one end to a power source (not shown) and at an opposite end to bushes 114 and 116 respectively. These bushes are biased into mechanical and electrical contact with respective slip rings 106 and 108.

The flange 104 is used to mechanically couple the slip ring body 102 via an intervening fixing bracket 118 to the arms 46a and 46b. The shaft 16 is connected to the slip rings 106 and 108 via a slip ring coupling 120. The slip ring coupling 120 is in the form of a ring which is mechanically connected to both the shaft 16 and the slip rings 106 and 108. Thus when the shaft 16 is rotated the slip rings 106 and 108 also rotate. Cables 122 and 124 are attached to each of the slip rings and extend through the shaft 16 to the electrical connector 98. Electrical connection between the power cables 110 and 112; and, the cables 122 and 124 is maintained by the brushed 114, 116 and slip rings 106, 108. As the slip rings, shaft 16 and receptacle 20 all rotate together, the cables 122 and 124 also rotate with the shaft 16 and thus do not twist. The coupling ring 120 sits on a weight bearing ring 125 that in turn rests on the inner race 48 of the ball bearing 50. In this way the weight of the shaft 16, receptacle 20 and tilt coupling 28 is placed on the slip ring coupling 120 and main bearing 50 rather than on the slip ring body 102.

System 10 also incorporates a control system 130 to enable control of the pan and tilt motors as well as the electrically powered device or devices 12 engaged in the receptacle 20. In this embodiment the control system 130 comprises two processors. One processor 132 is disposed in the housing 14, and the other processor 134 is disposed in the receptacle 20. The processor 132 is connected to the pan motor 18, tilt motor 26, and the limit switches 96a and 96b. In addition the processor 132 can be coupled with one or more data ports including USB sockets and card reader sockets shown generally as items 136. A communication system 138 is supported on the housing 14 and enables wireless communication with the processor 132. The communication system 138 is arranged to receive control signals from one or more of wired or wireless remote devices such as but not limited to a hand-held remote control, a wireless keyboard or a control console. This enables both instantaneous control signals to be fed to the system 10 to control the pan and tilt motion of receptacle 20, and also to enable the downloading of motor control software, software updates, and motion patterns for the receptacle 20. In one embodiment the communication system 138 may comprise an infrared receiver 140a and an infrared transmitter 140b.

The processor 132 is powered by a wired connection (not shown) to the power cables 110 and 112. The processor 134 is powered by connection with the cables 122 and 124. The communications systems associated with each processor in this embodiment is powered by wired connection to that processor.

The processor 134 is connected with the electrical connector 98 to exert control over the electrically powered device 12 coupled thereto. For example if the device 12 were a multi wavelength light emitter, the control system may exert signals to vary the wavelength of the light being emitted at any particular point in time. The communications system 138 also arranged to enable signals and data to be communicated to the processor 134. To this end, the communications system 138 also comprises in this embodiment an infrared receiver 142a and an infrared transmitter 142b. The processors 134 and 132 are able to communicate with each other via the communication system 138. Thus for example, signals or data to control the electrically powered device 12 can be communicated to the processor 132 and subsequently downloaded or transferred via the communication system to the processor 134. Additionally, a USB or other data ports 139 may be provided on the receptacle 20 to enable data and/or other control signals to be downloaded to the processor 134.

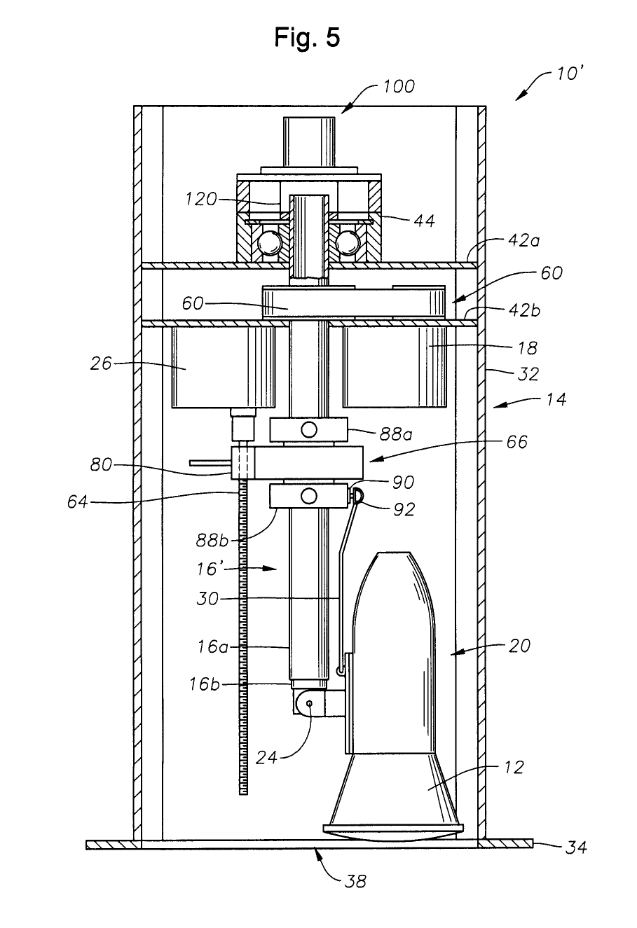

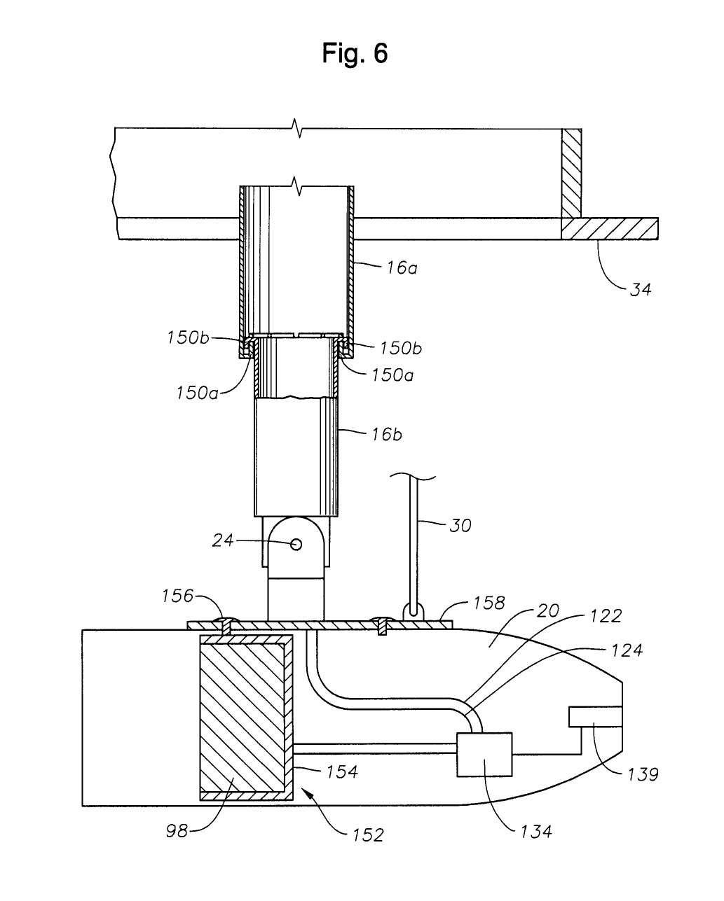

FIGS. 5 and 6 depict a modified form of the pan and tilt drive system 10′. All features and components of the system 10′ which are identical or have the same structure or function as corresponding components of the system 10 are denoted with the same reference numbers. However components which have been modified or varied are further designated with the ′ symbol.

The system 10′ functions in the same manner as the system 10 in terms of providing pan and tilt control as well as control over the electrically powered device 12. The substantive difference between the system 10 and 10′ is that in the system 10′ the receptacle 20 is able to be retracted into the housing 14. Thus for example if the housing 14 were a down light housing and mounted in a ceiling where the flange 34 abuts the ceiling, then in a retracted position the receptacle 20 would lie within the housing 14. Further, by the appropriate configuring of the coupling between the shaft 16 and the receptacle 20, the receptacle 20 can be positioned when in the retracted position so that the electrically powered device sits neatly within the opening 38 of a flange 34. In this instance the system 10 would have in substance the same appearance as a regular down light (assuming the electrically powered device were a light).

When the system 10 is operated to extend the shaft 16′ so that the tilt axis 24 is below the flange 34, the system 10′ operates in exactly the same manner as the system 10.

Providing the system 10′ with this retracted feature requires the housing 14′ to be longer than the housing 14, and the shaft 16′ to be in the form of a telescopically extendable and retractable shaft. FIG. 6 depicts a portion of the shaft 16′. The shaft 16′ is composed of an outer tuber 16a and an inner tube 16b. The tube 16b is slidable into and out of the tube 16a. The tubes 16a and 16b have respective engaging elements 150a and 150b which engage each other when the tube 16b is extended to a maximum position from tube 16a. These engaging portions 150a and 150b engage each other to transfer rotational motion of the tube 16a to the tube 16b so that the shaft 16′ rotates for the entirety of its length when in the fully extended position. Engaging portions 150a and 150b can take any form but in this embodiment comprise an upturned skirt on the tube 16a provided with a number of slots in which are seated a plurality of hooks 150b formed on the tube 16b.

FIG. 5 depicts the shaft 16′ in its fully retracted position with the receptacle 20 held within the housing 14 and pointing directly downwards. To initially extend the shaft 16′ the tilt motor 26 is operated to linearly translate the tilt coupling 28 downwardly along the outer tube 16a. As the tube 16b is connected to the tilt coupling 28 via the tilt rod 30 and receptacle 20, the tube 16b slides downwardly of the tube 16a. This motion continues until the tube 16b is in its fully extended position as shown in FIG. 6. Continued operation of the tilt motor 26 now has the effect of tilting the receptacle 20 about the tilt axis 24. It would be appreciated that at this time operation of the pan motor 18 will result in rotation of the entirety of the shaft 16′.

A further difference between the systems 10 and 10′ is the provision in the system 10′ of an adjustment mechanism 152 to enable the position of the socket 98 and thus the electrically powered device(s) 12, to be varied. In this particular embodiment the adjustment mechanism 152 is in the form of a simple mechanical bracket 154 which supports the socket 98 and is attached to the receptacle 20 via an adjusting screw 156. The screw can be loosened to enable the bracket 154 to be slid linearly along a rail plate 158 attached to the outside to receptacle 20. In a further variation a small stepper motor may be provided in the receptacle 20 to affect the linear motion of the bracket 154 along the rail plate 158. In yet a further minor variation, rails may be formed inside of the receptacle 20 on either side of the bracket 154 and along which the bracket 154 can be translated by use of a motor (not shown) held within the receptacle 20.

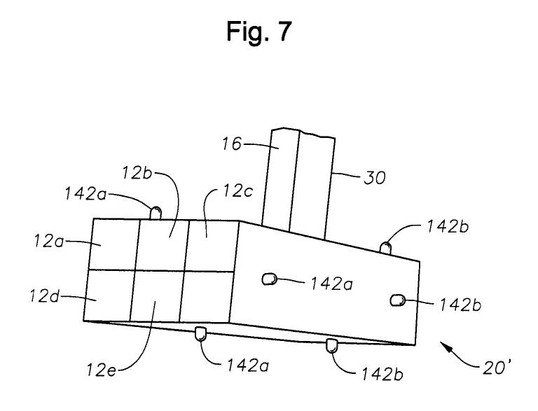

FIG. 7 depicts an alternate form of receptacle 20′ that may be used in conjunction with the system 10 or 10′. Receptacle 20′ differs from receptacle 20 depicted in earlier embodiments only by way of the number of electrically powered device(s) 12 that may be coupled thereto. In this embodiment the receptacle 20′ is depicted as supporting six separate electrically powered devices 12a-12f. Electrically powered devices 12a and 12f comprise speakers, electrically powered devices 12b and 12e comprise lights, electrically powered device 12c is a camera and electrically powered device 12d is a projector. Within the receptacle 20′ there is provided multiple electrical sockets, one for each of the devices 12a-12f. Each of the devices 12a-12f can be controlled separately either via the control system 130 and communication system 138; or, directly via separate hand-held or other remote controls. In this particular embodiment the receptacle 20′ supports multiple infrared receivers 142a and 142b which provide communications from separate controllers to the separate devices 12a-12f.

Now that embodiments of the pan and tilt drive system have been described in detail it will be apparent to those skilled in the arts that numerous variations and modifications may be made without departing from the basic inventive concepts. For example, the housing 14 may be mounted on or in a surface or on any other suitable support. For example the housing 10 may be mounted on a tripod or from a side wall rather than a ceiling. In addition the drive system may be provided with an additional rail and motor system to enable the entirety of the housing 14 to be extended and retracted from a wall or ceiling cavity. Also by providing system 10 with the control system 130 and communication system 138 the entirety of known electronic control and communication systems may be incorporated and used with the system 10.

In one variation, the control system may comprise only a single processor housed in either of the receptacle 20 or the housing 14 with the communication system being configured to enable the controller to communicate control signals to components in the other of the receptacle 20 and housing 14. In other variations, the communication system may be enabled to allow multiple pan and tilt drive systems to communicate with each other. Such embodiments may incorporate wireless transceivers (such as infrared receivers and transmitters) mounted on moveable platforms or arms to enable line of sight communication with other like drive systems. It would also be appreciated that the provision of the control and communication systems enables downloading of software drivers and control programmes for each of the electrically powered components (ie, motors 18, 26 and devices 12) of the system. In the above described embodiments, electrical power for the electrically powered devices 12 in receptacle 20 is provided via a slip ring arrangement. However in an alternate form, power may be inductively coupled to the devices 12 by use of primary and secondary transformer coils, one being stationary and for example fixed to the housing 14 while being attached to and rotating with the shaft 16.

In a further variation the tilt coupling 28 may be in the form of a pivot structure 170 as shown in FIG. 8. The pivot structure 170 comprises parallel bars 172 which are connected at one end by a transversely extending swivel bar 174. The swivel bar 174 is provided with a threaded hole which is engaged by the threaded rod 64. Opposite ends of the bars 172 are pivotally and slidably coupled to a fixed support bracket 176 internal of the housing 14. This coupling is via bolt 177 that passes through slots 179 formed in the bars 172 at ends distant the swivel bar 174. Each of the bars 172 is attached to the sleeve 76 via a block 178 which is retained between the stops 88a and 88b and is rotationally coupled from the sleeve 76. Pivot pins 180 extend from the block 178 and seat within longitudinal slots 182 formed in each of the bars 172. The tilt rod 30 is pivotally attached to stop 88b. Thus as the pan motor 26 is operated and the shaft 64 rotated, the pivot structure 170 is pivoted about the pivot pins 180 thereby linearly translating the sleeve 76 and thus the tilt rod 30.

In a further variation one or both of the pan and tilt motors 18, 26 can be mounted between the plates 42a and 42b and more particularly on the plate 42b. In addition a cover can be placed about the portions of the shaft 16 and tilt rod 30 which extend form the housing 14. In embodiments for example where the shaft is extendable the cover may have a concertina like structure to enable it to extend longitudinally. Although this is not essential and a simple rigid not extendable cover which may be in the cross sectional shape of a circle, tear drop or aerofoil can be placed about the shaft 16 and rod 30.

All such modifications and variations together with others that would be obvious to persons of ordinary skill in the art are deemed to be within the scope of the present invention the nature of which is to be determined from the above description and the appended claims.

1. A pan and tilt drive system for an electrically powered device, the system comprising:
a housing;
a shaft rotatably supported in the housing;
a pan motor disposed to rotate the shaft about a longitudinal axis of the shaft;
a receptacle coupled to the shaft about a tilt axis, the receptacle disposed to support an electrically powered device; and,
a tilt subsystem disposed to facilitate tilt motion of the receptacle about the tilt axis, the tilt subsystem having a tilt motor disposed in the housing, a tilt coupling and a tilt rod, the tilt coupling coupled between the tilt motor and the tilt rod, and the tilt rod coupled between the tilt coupling and the receptacle, the tilt coupling arranged to effect linear translation of the tilt rod in a direction parallel to the longitudinal axis to effect tilt motion of the receptacle about the tilt axis.

2. The pan and tilt drive system according to claim 1, wherein the tilt coupling is slidably supported on the shaft.

3. The pan and tilt drive system according to claim 2, wherein the tilt coupling comprises a sleeve mounted on the shaft and a tilt link carried by the sleeve and rotationally decoupled from the sleeve.

4. The pan and tilt drive system according to claim 3, wherein the sleeve is provided with axially spaced apart stops between which the tilt link is retained.

5. The pan and tilt drive system according to claim 4, wherein each stop comprises a ring extending radially from and circumferentially about the sleeve.

6. The pan and tilt drive system according to claim 3, wherein the tilt link comprises a bearing block coupled to the tilt motor, wherein operation of the tilt motor effects a linear motion of the bearing block along the longitudinal axis, wherein the tilt rod is coupled to the sleeve.

7. The pan and tilt drive system according to claim 3, wherein the tilt link comprises a slip ring retained on the sleeve and a member having first and second opposite ends, the member pivotally connected intermediate of its ends to the slip ring, wherein the first end of the member is coupled the tilt motor wherein operation of the tilt motor effects a pivoting of the member and the tilt rod is connected to the second end of the member.

8. The pan and tilt drive system according to claim 1, wherein the receptacle is suspended from the housing.

9. The pan and tilt drive system according to claim 1, wherein the housing comprises a plate through which the shaft and tilt rod extend at offset locations, the plate being rotatably supported in the housing in a plane perpendicular to the longitudinal axis.

10. The pan and tilt drive system according to claim 1, wherein the shaft is extendable and retractable along the longitudinal axis in the receptacle is movable between a retracted position where the receptacle is disposed within the housing and an extended position where the receptacle is disposed outside of the housing.

11. The pan and tilt drive system according to claim 1, comprising an electrical conductor extending through the housing, the electrical conductor enabling flow of electric current between an electric power source and an electrically powered device engaged in the receptacle.

12. The pan and tilt drive system according to claim 11, wherein the electrical conductor passes through the shaft.

13. The pan and tilt drive system according to claim 11, comprising an electrical connector disposed in the receptacle, the electrical connector electrically coupled to the electrical conductor and configured to electrically connect to an electrically powered device.

14. The pan and tilt drive system according to claim 1, comprising a control system arranged to control one or more of: the pan motor, the tilt motor and an electrically powered device engaged in the receptacle.

15. The pan and tilt drive system according to claim 14, wherein the control system comprises one or more processors disposed in one or both of the housing and the receptacle.

16. The pan and tilt drive system according to claim 15, wherein one or more of the processors comprise an associated electronic memory.

17. The pan and tilt drive system according to claim 14, further comprising a communications system enabling either or both signals and data to be communicated between a remote device and the control system to control one or more of: the pan motor, the tilt motor and an electrically powered device.

18. The pan and tilt drive system according to claim 1, wherein the receptacle is arranged to engage a plurality of electrically powered devices.

19. The pan and tilt drive system according to claim 18, wherein two or more of the plurality of electrically powered devices produce different outputs.

20. A pan and tilt drive system for an electrically powered device, the system comprising:
a housing;
a shaft having a first end and a second end and characterized by a shaft axis, wherein the shaft is rotatably supported in the housing;
a first motor disposed to rotate the shaft about the shaft axis;
a mounting plate pivotally attached to one end of the shaft, wherein the mounting plate pivots about a tilt axis that is perpendicular to the shaft axis;
a sleeve slidingly mounted on the shaft;
tilt linkage engaging the plate and the sleeve; and
a second motor coupled to the sleeve, the second motor disposed to urge the sleeve axially along the shaft axis.

21. The pan and tilt drive system according to claim 20, further comprising
an elongated, threaded rod coupled to the second motor, the threaded rod extending substantially parallel to the shaft axis, the second motor disposed to cause rotation of the threaded rod;
first and second stops mounted on the sleeve and axially spaced apart from one another;
a bearing block mounted on the sleeve between the two stops, the bearing block including a threaded through-bore disposed substantially parallel to the shaft axis, wherein the threaded rod threadingly engages the threaded through-bore, wherein the bearing block is axially and rotationally decoupled from the sleeve.

22. The pan and tilt drive system according to claim 20, wherein the shaft comprises a first portion and a second portion, wherein the second portion of the shaft is mounted in the first portion of the shaft and axially movable relative thereto, wherein the shaft further comprises an engagement mechanism to fix relative movement of the first and second portions.
